(19) United States
(12) Patent Application Publication
(10) Pub. No.: US 2009/0055706 A1
(43) Pub. Date: Feb. 26, 2009

(54) METHOD AND APPARATUS FOR FLASH MEMORY ERROR CORRECTION

(75) Inventor: Li-Lien Lin, Hsinchu City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 11/842,268

(22) Filed: Aug. 21, 2007

(51) Int. Cl. H03M 13/31; H03M 13/00; H03M 13/07

(52) U.S. Cl. 714/758; 714/752; 714/784; 714/E11.023

(57) ABSTRACT

Error correction method and a flash memory device are provided. In the flash memory device, a memory array comprises a main area for data storage, and a spare area for storage of parities associated with the stored data. An erasure table maintains an erasure list indicating addresses of defects in the memory array where data storage is unavailable. A processor performs error correction on the stored data based on the parities and the erasure list to output a corrected output.

### BACKGROUND OF THE INVENTION

1. Field of the Invention

The invention relates to flash memory, and in particular, to an enhanced error correction for a multi-level cell flash memory device.

2. Description of the Related Art

FIG. 1 shows a memory array 100 comprising a main area 102 and a spare area 104. Conventionally, a memory array 100 is made up of single-level cells (SLC) in which only two states 0 and 1 are presented. As the capacity increases, possibility of erroneous cells also increases. Thus, error correction is prevalently implemented in the memory array 100. The main area 102 consumes the major capacity for storage of data bytes, and the spare area 104 stores parity information enabling fault tolerance for the stored data. Error correction codes (ECC) are referred to various algorithms to recover correct information from partially corrupted data. As an example, Reed Solomon Coding is a widely used algorithm to detect and correct errors. If 2N parities are provides, an erroneous data block of at most N errors is still correctable. For example, in the memory array 100 of SLC type, a data block of 2048 bytes is associated with 64 bytes parities, thus a maximum of 32 errors are allowable in the data block. The capability of fault tolerance depends on the amount of spare area 104, however, the capacity of memory array 100 is limited, and the cost to increase the spare area 104 is deemed too high to be feasible.

FIG. 2 is a flowchart of a conventional error correction method. In step 202, a data block stored in the main area 102 is read along with its associated parities. In step 204, based on the parities, an error correction algorithm such as Reed Solomon decoding is performed to detect potential errors in the data block. In step 206, the total number of errors is counted to determine whether the data block is recoverable. For example, the number of parities associated with the data block is 2N, thus, at most N errors are correctable. In step 210, If the number of errors does not exceed N, the data block is error corrected and output. Otherwise, in step 208, the data block is discarded.

For a multi-level cell (MLC) type flash memory, a cell may store more than two states 0 and 1, so the probability of error is much higher than that of a SLC type. The described error correction may not be sufficient to protect information. Thus, an enhancement is desirable.

### BRIEF SUMMARY OF THE INVENTION

An exemplary embodiment of a flash memory device is provided, in which a memory array comprises a main area for data storage, and a spare area for storage of parities associated with the stored data. An erasure table maintains an erasure list indicating addresses of defects in the memory array where data storage is unavailable. A processor performs error correction on the stored data based on the parities and the erasure list to output a corrected output.

The processor performs the error correction using Reed-Solomon algorithm. The memory array may be made up of multi-level cells (MLC), and as a minimum requirement for the MLC type flash memory device, the memory array provides at least 16 bytes parity for every 512 byte of data.

The processor further discovers new defects in the memory array while performing the error correction, and the erasure table updates the erasure list upon detecting a new defect by the processor. The erasure list may be established by writing known values to the memory array and comparing them with the readouts therefrom. The entries stored in the erasure list may be of an erasure power form, erasure address or flags.

When a data block is requested, the processor reads the data block from the memory array along with corresponding parities, thereby an error detection is performed based on the algorithms to count the number of erasures associated with the data block and the number of errors detected in the data block, to determine whether the data block is correctable. The error detection is basically the same algorithm as error correction, such as Reed Solomon decoding.

The processor performs error correction on the data block only when the following equation is met:

2E+S<2N

Where E is the number of errors, S is the number of erasures, and 2N is the number of parities.

Another embodiment provides an error correction method implemented in the flash memory device, and a detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a memory array 100 comprising a main area 102 and a spare area 104;

FIG. 2 is a flowchart of a conventional error correction method;

FIG. 3 shows an embodiment of a flash memory device; and

FIG. 4 is a flowchart of the error correction method according to the invention.

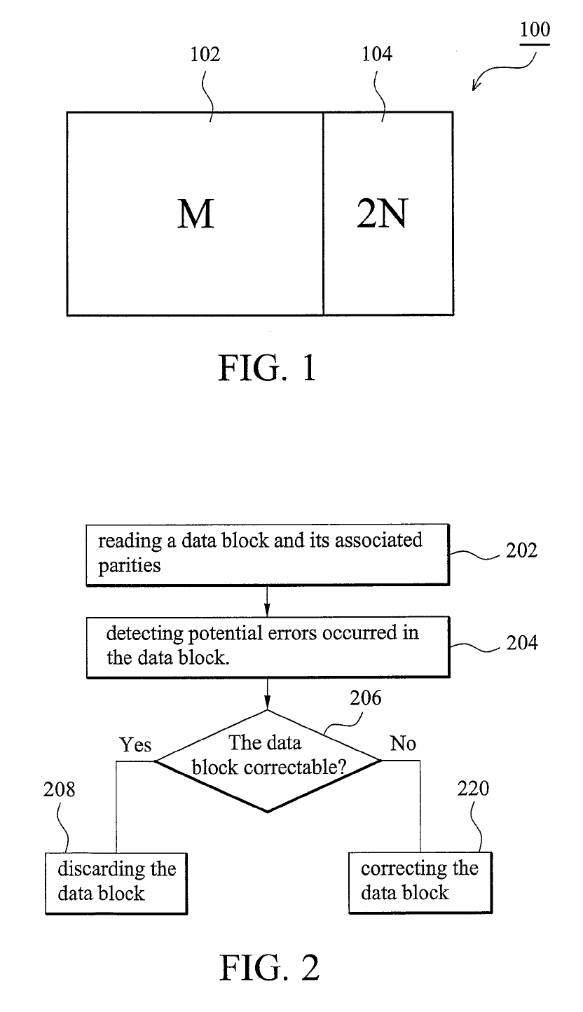

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

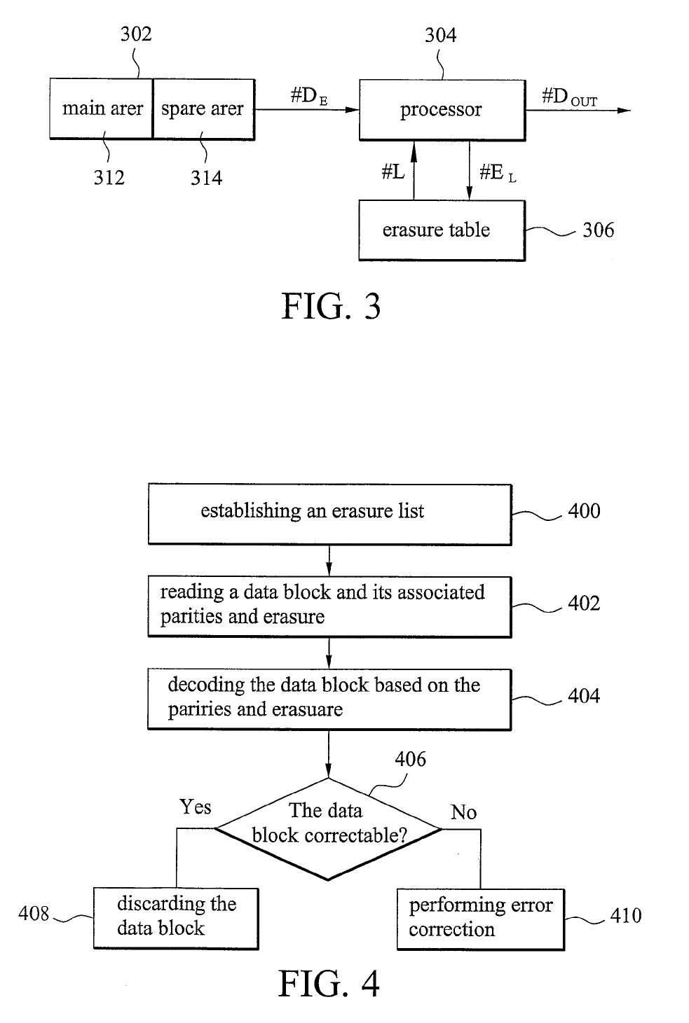

FIG. 3 shows an embodiment of a flash memory device, comprising at least three major components. A memory array 302 is a storage array divided into a main area 312 and a spare area 314, where the main area 312 stores data, and the spare area 314 stores parities associated with the stored data or some information. An erasure table 306 is provided to maintain an erasure list indicating addresses of defects in the memory array 302 where data storage is unavailable. When data stored in the memory array 302 is requested for access, the processor 304 performs error correction on the stored data based on the error parities and the erasure list to output a corrected output #D_{OUT}.

According to error correction theory, the ability to recover data is increased when specific addresses in the memory array 302 are known defects. Therefore with the help of an erasure list, the memory array 302 is capable of tolerating more errors. As an embodiment, the processor 304 may use Reed-Solomon code algorithm. Various algorithms may also be useful, such as Hamming code, BCH code, Reed-Muller code, Binary Golay code, convolutional code, and turbo code. The memory array 302 is particularly made up of multi-level cells (MLC), each of which may represent a multi-state more than just 0 or 1.

The erasure list may be established by calibration at the manufacturing stage. For example, the processor 304 may establish a new erasure list by writing known values to the memory array 302 and comparing that with the readouts therefrom. On the other hand, new errors may occur through durable and repetitive usage. The processor 304 discovers new defects in the memory array 302 while performing the error correction, and in response, the erasure table 306 accordingly updates the erasure list when a new defect is detected by the processor 304.

The format of erasure list is not limited. For example, addresses of defects may be directly stored in the erasure table 306, or a flag for indicating the address of the defects. Alternatively, addresses of defects may be stored in an erasure power form which is directly adoptable for Reed Solomon decoding operations.

When a data block is requested, the processor 304 obtains the data block from the memory array 302 along with parity bytes and send them to the processor 304. In the processor 304, decoding of the data block and the parities is performed, and the data block is deemed correctable only when the following condition is met:

2E+S<2N (1)

Where E is the number of errors, S is the number of erasures, and 2N is the number of parities. In other words, at most 2N errors are allowable when the erasure list is incorporated for error correction.

FIG. 4 is a flowchart of the error correction method according to the invention. The error correction adapting the erasure list is summarized as the following steps. In step 400, an erasure list is established for maintaining addresses of defects in the memory array 302 where data storage is unavailable. In step 402, a data block is read in response to a request, along with its associated parities and erasure. In step 404, the parities and erasure along with the data block are substituted into the processor 304 for data decoding. In step 406, the condition to perform error correction is determined. If the equation (1) is met, error correction is performed in step 410. Otherwise, if not, the data block is deemed unrecoverable and discarded in step 408.

While the invention has been described by way of example and in terms of preferred embodiment, it is to be understood that the invention is not limited thereto. To the contrary, it is intended to cover various modifications and similar arrangements (as would be apparent to those skilled in the Art). Therefore, the scope of the appended claims should be accorded the broadest interpretation so as to encompass all such modifications and similar arrangements.

What is claimed is:

1. A flash memory device, comprising:
a memory array, comprising a main area for data storage, and a spare area for storage of parities associated with the stored data;
an erasure table, maintaining an erasure list of defects in the memory array where data storage content maybe not correct;
a processor, performing error correction on the stored data based on the parities and the erasure list to output a corrected output.

2. The flash memory device as claimed in claim 1, wherein the processor performs the error correction using Reed-Solomon algorithm.

3. The flash memory device as claimed in claim 1, wherein the memory array is made up of multi-level cells (MLC).

4. The flash memory device as claimed in claim 3, wherein the memory array provides at least 16 parities for every 512 byte of data.

5. The flash memory device as claimed in claim 1, wherein:
the processor further discovers new defects in the memory array while performing the error correction; and
the erasure table updates the erasure list when a new defect is detected by the processor.

6. The flash memory device as claimed in claim 1, wherein the processor establishes the erasure list by writing known values to the memory array and comparing them with the readouts therefrom.

7. The flash memory device as claimed in claim 1, wherein the erasure list comprises addresses of defects in an erasure power form.

8. The flash memory device as claimed in claim 1, wherein:
the processor obtains a data block from the memory array along with corresponding parities;
the processor performs an data decoding based on the data block with parities to determine whether the data block is correctable.

9. The flash memory device as claimed in claim 8, wherein:
the processor performs error correction on the data block only when the following equation is met:
2E+S<2N
where E is the number of errors, S is the number of erasures, and 2N is the number of parities.

10. An error correction method for a flash memory device, wherein the flash memory device comprises a memory array, comprising a main area for data storage, and a spare area for storage of parities associated with the stored data; the error correction method comprises
establishing an erasure list for maintaining defects in the memory array where data storage content maybe not correct;
performing error correction on the stored data based on the parities and the erasure list to output a corrected output.

11. The error correction method as claimed in claim 10, wherein the error correction uses Reed-Solomon algorithm.

12. The error correction method as claimed in claim 10, wherein the memory array is made up of multi-level cells (MLC).

13. The error correction method as claimed in claim 12, further comprising providing at least 16 parities for every 512 byte of data.

14. The error correction method as claimed in claim 10, further comprising:
discovering new defects in the memory array while performing the error correction; and
updating the erasure list when a new defect is detected.

15. The error correction method as claimed in claim 10, further comprising establishing the erasure list by writing known values to the memory array and comparing with the readouts therefrom.

16. The error correction method as claimed in claim 10, wherein the erasure list comprises addresses of defects in an erasure power form.

17. The error correction method as claimed in claim 10, further comprising:
reading a data block from the memory array along with corresponding parities;
performing an data decoding based on the data block with parities and thereby determining whether the data block is correctable.

18. The error correction method as claimed in claim 17, further comprising:
performing error correction on the data block only when the following equation is met:
2E+S<2N
where E is the number of errors, S is the number of erasures, and 2N is the number of parities.
